(19) United States
(12) Patent Application Publication
(10) Pub. No.: US 2024/0339554 A1
(43) Pub. Date: Oct. 10, 2024

(54) PROCESS FOR MANUFACTURING A STARTING MATERIAL FOR A SILICON SOLAR CELL HAVING PASSIVATED CONTACTS

(71) Applicant: SINGULUS TECHNOLOGIES AG, Kahl am Main (DE)

(72) Inventors: Benjamin MANDLMEIER, Pöcking (DE); Philipp NOACK, Maisach (DE); Bianca WATTENBERG, Alling (DE); Mirza CORDA, Maisach (DE); Peter WOHLFAHRT, Kahl am Main (DE); Simon HÜBNER, Seligenstadt (DE)

(21) Appl. No.: 18/576,026

(22) PCT Filed: Jun. 21, 2022
(86) PCT No.: PCT/EP2022/066847

§ 371 Date: Jan. 2, 2024

(30) Foreign Application Priority Data
Jul. 2, 2021 (DE) 10 2021 003 446.5

(51) Int. Cl. H01L 31/18

(52) U.S. Cl. CPC H01L 31/1804; H01L 31/1864

(57) ABSTRACT

The present invention is directed to a process for manufacturing a starting material for a silicon solar cell having passivated contacts, a system for carrying out the process, and an intermediate product resulting from the process.

The present invention is directed to a process for manufacturing a starting material for a silicon solar cell having passivated contacts, to a system for carrying out said process, and to an intermediate product resulting from the process.

For solar cells on the basis of crystalline silicon wafers that use the technology of so-called “passivated contacts”, as described for example in WO 2018/102852 A1, the generation of a thin silicon oxide layer is required (see for example F. Feldmann et al., Solar Energy Materials and Solar Cells 120, 270 (2014)). These tunnel oxide or charge carrier transport layers typically have a thickness between 1.4 nm and 6 nm. Cost-effective processes for their preparation include wet chemical oxidation in aqueous solution and thermal oxidation in the gas phase at elevated temperatures typically greater than 150° C. and less than 600° C.

The wet chemical process is particularly advantageous, since in this process the substrate surface can be chemically passivated in one and the same system immediately after cleaning and surface structuring without contamination. Reloading in a tube furnace and the associated possible contamination of the bare silicon surface are thus avoided.

However, compared to the thermal layers, the wet-chemically generated layers with a thickness of typically 1.4 nm to 1.8 nm are often not sufficiently stable to withstand subsequent high-temperature thermal processes of long duration. At high thermal stress, the wet-chemically generated silicon oxide tunnel layers lose some of their electronic properties useful in solar cell manufacture, such as passivation and barrier to diffusion of foreign substances (see, for example, R. van der Vossen, Energy Procedure, 124 (2017), 448-454).

However, to produce passivated contacts, a subsequent thermal process is necessary for two reasons. On the one hand, an amorphous silicon layer applied later to the tunnel oxide must be recrystallized to achieve the desired polycrystalline structures. On the other hand, the dopant, which is either applied directly with the subsequent silicon layer or made available later from the gas phase or by means of another highly doped layer to be applied, must be driven through the oxide layer into the underlying semiconductor by means of the thermal process.

In addition, depending on the type of manufacturing process for the tunnel oxide layer, waiting times between the generation of the tunnel oxide and the subsequent process step, i.e. the application of the polycrystalline silicon layer, and the ambient conditions prevailing during this process, such as temperature, humidity and purity of the ambient air, an undesirable change in the properties of the tunnel oxide layer may occur. Its surface can be contaminated by dust or aerosols, for example. In the case of a very thin tunnel oxide layer, its thickness may increase due to uncontrolled further oxidation. The function of the passivated contact can therefore be impaired either due to undesired impurities caused by contamination or due to undesired changes in the structure or thickness of the tunnel oxide layer.

Against this background, one problem of the present invention is to provide an improved process for manufacturing a starting material for a silicon solar cell having passivated contacts, wherein in particular the thermal stability of the silicon oxide layer is to be increased by means of the improved process. A further problem of the present invention is to improve the process in such a way that the thickness, the structure and the purity of the silicon oxide layer can be better controlled compared to existing processes.

This problem is solved by a process according to claim 1 as well as a system for carrying out the process according to claim 22. Claim 26 is directed to a correspondingly improved intermediate product in the manufacture of a starting material for a silicon solar cell having passivated contacts.

Accordingly, the present invention is directed to a process for manufacturing a starting material for a silicon solar cell having passivated contacts, in which first a silicon wafer having a first side and a second side is provided, wherein the silicon wafer comprises a first silicon oxide layer on at least the first side. Said first silicon oxide layer on the first side of the silicon wafer is then coated with a second silicon oxide layer by means of physical or chemical vapor deposition, optionally after an additional in-situ plasma intermediate treatment. Coating by means of cathode sputtering or plasma-enhanced chemical vapor deposition (PE-CVD) is particularly preferred. Subsequently, the second silicon oxide layer is coated with at least a third layer comprising amorphous silicon and/or polycrystalline silicon and/or nanocrystalline silicon.

Both the optional intermediate treatment and the deposition of the second silicon oxide layer and the third layer are preferably carried out in a single continuous system, preferably in a dynamic in-line process, which will be explained in detail below.

The silicon oxide layer present on the first side of the silicon wafer can be obtained by oxidizing at least the first side of a silicon wafer by thermal and/or wet chemical oxidation and/or by a plasma treatment process. Alternatively, the silicon oxide layer may be a native silicon oxide layer formed, for example, during storage of the silicon wafer in air.

In other words, according to the invention, the thermal stability of the silicon oxide layer is to be increased, for example, by again applying a second silicon oxide layer by means of physical or chemical vapor deposition after wet chemical oxidation in order to increase the overall thickness of the silicon oxide (consisting of first and second silicon oxide layers). This not only increases the thermal stability of the silicon oxide layer thus formed. Rather, by precisely adjusting the density and thickness of the second silicon oxide layer, the barrier effect of the overall silicon oxide layer for the penetration of dopants into the silicon wafer from neighboring layers can be specifically adjusted. In addition, the second silicon oxide layer can be doped with foreign substances from the third and/or fifth main group in order to adjust, optionally supported by a subsequent thermal process, the dopant concentration in the amorphous silicon layer and/or in the layer of the silicon substrate adjacent to the tunnel oxide layer.

In an alternative embodiment, the first silicon oxide layer may be treated with a plasma treatment process prior to applying the second silicon oxide layer. This additional plasma treatment serves, for example in case of an undesired contamination or surface change of the first oxide layer, to clean and/or activate the surface of the first silicon layer and thus to reduce impurities which would cause a charge carrier recombination and thus a reduction of the solar cell efficiency.

Such cleaning can, alternatively or additionally, also be carried out by heating the substrates before deposition of the second layer (i.e. before deposition of the undoped silicon oxide). For this purpose, the substrates can be heated to at least 100° C., preferably to above 150° C., in a vacuum under a defined atmosphere prior to coating. The substrates can then be maintained at this temperature during coating with the second silicon oxide layer or be further increased. The increased substrate temperature can also significantly improve the quality of the layer.

Heating can be carried out by means known to the skilled person, for example by means of resistance heaters or IR radiation. The defined atmosphere preferably comprises a reduced pressure compared to the atmospheric pressure of less than 1 mbar, preferably of less than 0.01 mbar. Additionally, the defined atmosphere may include air, inert or oxidizing gases, and mixtures thereof. The purifying effect of the heating step, e.g. by evaporating volatile substances such as water, can be further enhanced by providing a chemically dry-etching fluorine-containing gas mixture.

In the case of an unintentionally overly thick first oxide layer, the intermediate plasma treatment can also be used to reduce the thickness of the first oxide layer and/or to activate the surface.

Depending on the desired application, the intermediate plasma treatment process can be designed in a more gentle or more abrasive manner. By selecting the process gas, the process pressure and the plasma density, the effect of the process can be adapted to the requirements, from light surface activation to reactive ion etching.

Overall, the combination of the first oxide layer, the optional intermediate plasma treatment and the application of the second oxide layer in combination with the application of the doped silicon layer (third layer) allows the properties of the passivated contact to be specifically adjusted.

The first silicon oxide layer preferably has a thickness of 0.5 nm to 3 nm, more preferably 1.0 nm to 2.5 nm, and particularly preferably 1.0 nm to 2.0 nm. The second silicon oxide layer preferably has a thickness of 0.1 nm to 5 nm and more preferably of 0.5 nm to 2 nm.

The thickness of the first silicon oxide layer can be adjusted, depending on the process selected for the oxidation, in particular by suitable selection of the concentration and reaction time of the oxidizing medium: The higher the concentration of the oxidizing medium and its reaction time, the thicker and denser the SiO₂ layer will be. The thickness and density of the layer can also be improved by increasing the temperature, although in some processes the temperature is only suitable for adjustment to a limited extent since, for example, when ozone is used as the oxidizing medium, the temperature can only be increased to a limited extent (max. to 50° C.) since otherwise the ozone concentration becomes too low.

Particularly preferably, the formation of the first silicon oxide layer on at least the first side of the silicon wafer takes place by wet chemical oxidation at a temperature of at least 40° C. and/or an ozone concentration of at least 30 ppm.

The thickness of the second silicon oxide layer can be specifically adjusted by the rate and duration of the vapor deposition. In the case of plane-parallel silicon oxide layers, their thickness can be determined, for example, by means of ellipsometry and the process parameters of the vapor deposition can then be adjusted accordingly. For textured silicon wafers, the setting of the desired thickness can be determined, for example, by scaling the rate and/or duration of the vapor deposition according to the ratio of the enlarged textured surface to the plane-parallel surface. In the context of the present invention, the thickness of the silicon oxide layer always is to be defined perpendicular to the local surface normal, so that, for example, in the case of a pyramid texture, the thickness of the silicon oxide layer corresponds to the layer thickness measured perpendicular to the lateral surface of the pyramid. If the layer thickness varies, as is regularly the case with such pyramid textures, the layer thickness according to the invention is to refer to the thickness averaged over the entire surface.

Preferably, the silicon wafer with the first silicon oxide layer is rinsed and dried prior to the optional intermediate plasma treatment and coating with the second silicon oxide layer (i.e., optionally after, for example, wet chemical oxidation).

After deposition of the first silicon oxide layer, the wafer surface can continue to react uncontrollably with atmospheric oxygen, which can have a negative effect on the stability, density and/or stoichiometry of the silicon oxide. Therefore, it is desirable to achieve an as direct or immediate further processing as possible by the optional intermediate plasma treatment and/or coating of the first silicon oxide layer with the second silicon oxide layer. Thus, it is preferred that the coating of the first silicon oxide layer with the second silicon oxide layer or (in the case of the optional intermediate plasma treatment) the treatment with plasma takes place within 48 h, preferably within 24 h, particularly preferably within 12 h after completion of the coating of the first silicon oxide layer with the second silicon oxide layer.

Coating of the second silicon oxide layer with at least the third layer is also preferably performed by means of physical or chemical vapor deposition, and particularly preferably by means of cathode sputtering or plasma-enhanced chemical vapor deposition (PE-CVD).

The third layer preferably comprises a dopant, which is preferably an element from the third or fifth main group.

The tunnel oxide layer according to the invention can also be provided on both sides of the silicon wafer. Accordingly, the silicon wafer provided may comprise a first silicon oxide layer on the first side and on the second side, respectively. These two first silicon oxide layers may be, for example, native oxide layers. Alternatively, simultaneously with the oxidation of at least the first side, also the second side of the silicon wafer can be oxidized by thermal and/or wet chemical oxidation and/or by a plasma treatment process to obtain a first silicon oxide layer on the second side. The latter is particularly advantageous, since usually the entire surface of the silicon wafer is oxidized during thermal or wet chemical oxidation (for example by immersion in a batch and/or in-line process).

Furthermore, the first silicon oxide layer on the second side can both be optionally treated with an intermediate plasma treatment process and be coated with a second silicon oxide layer. For this purpose, physical or chemical vapor deposition is preferably used and cathode sputtering or PE-CVD are particularly preferably used.

Furthermore, the first silicon oxide layer on the second side or the second silicon oxide layer on the second side can also be coated with at least one doped silicon layer, which preferably comprises an element from the third or fifth main group. Preferably, the doping of this doped silicon layer is opposite to the third layer on the first side of the silicon wafer.

This doped silicon layer is also preferably applied (optionally together with the dopants) by means of physical or chemical vapor deposition, and particularly preferably applied by means of cathode sputtering or PE-CVD.

Both the optional intermediate treatment and the deposition of the second silicon oxide layer and the third layer on the second side of the silicon wafer are preferably carried out in a single continuous system, preferably in a dynamic inline-process. Particularly preferably, both sides of the silicon wafer are treated in a single continuous system, preferably in a dynamic inline-process.

Preferably, the method further comprises annealing the coated silicon wafer at a temperature of at least 700° C. This annealing preferably causes a doped silicon layer to be formed in the silicon wafer on the first side below the first silicon oxide layer and/or causes a doped silicon layer to be formed in the silicon wafer on the second side below the first silicon oxide layer.

The doping level of the formed doped silicon layer(s) preferably depends on the thickness and/or the density of the second silicon oxide layer on the first and second sides, respectively.

Preferably, annealing of the coated silicon wafer in combination with plasma treatment and coating takes place in a system that can consist of several sections.

The present invention is further directed to a system for carrying out the process described above. In a particularly preferred embodiment, this system comprises a basin for wet chemical oxidation of a silicon wafer and a cathode sputtering unit or a PE-CVD unit for coating with a silicon oxide layer. Furthermore, an optional plasma treatment unit as well as a further cathode sputtering unit or PE-CVD unit for coating with amorphous silicon and/or polycrystalline silicon and/or nanocrystalline silicon is provided.

The present invention is further directed to an intermediate product in the manufacture of a starting material for a silicon solar cell having passivated contacts. The intermediate product comprises a silicon wafer having a first side and a second side, a first silicon oxide layer on at least the first side, and a second silicon oxide layer directly on the first silicon oxide layer. Further, a third layer is provided directly on the second silicon oxide layer comprising amorphous silicon and/or polycrystalline silicon and/or nanocrystalline silicon.

The first silicon oxide layer preferably has a thickness of 0.5 nm to 3 nm, more preferably 1.0 nm to 2.5 nm, and particularly preferably 1.0 nm to 2.0 nm. The second silicon oxide layer preferably has a thickness of 0.1 nm to 5 nm and more preferably a thickness of 0.5 nm to 2 nm. The thicknesses of the first and second silicon oxide layers can be determined (by comparison with a calibration layer) by means of ellipsometry.

The second silicon oxide layer preferably has a density from 2.10 g/cm³ to 2.65 g/cm³, more preferably from 2.20 g/cm³ to 2.40 g/cm³.

The third layer preferably comprises a dopant which is preferably an element from the third or fifth main group. The density as well as the thickness of the second silicon oxide layer are preferably adjusted in such a way that the second silicon oxide layer has a diffusion coefficient of greater than 1×10⁻¹⁸ cm²/s, preferably greater than 5×10⁻¹⁷ cm²/s, at a temperature of 1100° C. for the dopant of the third layer. In principle, the denser and the thicker the second silicon oxide layer, the smaller the diffusion coefficient. Therefore, the diffusion coefficient can be adjusted via the corresponding coating process in a targeted manner.

As explained above with reference to the method, the silicon wafer may comprise a first silicon oxide layer on the first side and on the second side, respectively. Furthermore, a second silicon oxide layer may also be provided on the first silicon oxide layer on the second side of the silicon wafer. Alternatively or additionally, a doped silicon layer may also be provided on the second side, preferably comprising an element from the third or fifth main group, wherein the doping is preferably opposite to the doping of the third layer on the first side of the silicon wafer.

By combining two oxide layers according to the invention, the resulting overall tunnel oxide layer can be optimally adapted to the requirements of a solar cell having passivated contacts. On the one hand, even after the e.g. wet-chemically generated oxide was reinforced with the second oxide layer, the layer remains thin enough to act as a tunnel oxide or as a thin charge carrier transport layer. On the other hand, the second oxide layer stabilizes the e.g. wet-chemically generated oxide in such a way that the passivation properties of the overall layer are maintained by a subsequent thermal treatment. Furthermore, by adjusting the density and thickness of the second silicon oxide layer, the diffusion properties of the resulting tunnel oxide for a dopant (for example, phosphorus or boron) can be adjusted in such a way that the dopant can be driven into the silicon crystal located below the oxide layer in precisely adjustable concentrations during subsequent thermal processes. The latter is possible, for example, in the case of coating by means of cathode sputtering by varying the process pressure, the voltage and the substrate temperature. By adjusting the density and thickness of the PVD layer, the diffusion properties of the entire oxide layer can be adjusted.

The thickness and surface properties of the first silicon oxide layer can furthermore be optimized with an optional, intermediate plasma treatment step in such a way that the overall oxide layer can be optimally calibrated in its function as tunnel oxide for passivated contacts after deposition of the second silicon oxide layer. Depending on the properties of the first silicon oxide layer, this optional plasma treatment can achieve either that said layer is cleaned and its surface is activated or, in addition, that its thickness is reduced by more aggressive etching.

An advantage of these processes is that the surface of the silicon wafer, which was cleaned before the deposition of the first oxide layer, is protected by the first oxide layer applied immediately after cleaning, e.g. by wet chemical means, and the positive surface properties of the wafer are preserved. On the basis of the invention, said protective function of the oxide layer acts independently of its intended function as a tunnel barrier. The invention allows the first, protective oxide layer to be converted into a tunnel oxide layer that is optimally adapted to the overall system both by optional intermediate plasma treatment and by applying the second oxide layer by PVD or PE-CVD.

The use of physical vapor deposition (PVD), in particular cathode sputtering, to increase the thickness of the silicon oxide layer is particularly cost-effective. Moreover, it can be done immediately before PVD coating of the wafer with amorphous silicon, as is necessary for cell architectures that use passivated contacts. Thus, a single system can be used both to increase the thermal load capacity of the tunnel oxide layer and to coat it with amorphous silicon.

The sputtering process is useful for the targeted deposition of thin, homogeneous multilayer systems. Thus, the combined properties of the layer stack can be adjusted by precisely set individual layers (silicon, barrier and dopant layers). Sputtering is easily controllable and acts unilaterally, which is an advantage in the production of passivated contacts.

As an alternative to sputtering, the oxides and the silicon layers can also be applied using PE-CVD. Both are plasma-based vacuum-thin film deposition processes, which are characterized by low contamination and, in the inline continuous process, also by high layer uniformity and high throughput. Furthermore, both coating processes can be well controlled or regulated and combined with other plasma treatment processes, such as plasma etching, plasma oxidation, plasma cleaning or plasma activation, as well as with upstream or downstream annealing processes.

Wet chemical oxidation is advantageous in that a wet chemical system is required for cleaning and texturing the silicon substrates at the beginning of their manufacturing process of crystalline silicon substrate cells. Thus, cleaning, texturing and formation of a silicon oxide layer can be combined in a single wet chemical system. The wet-chemically generated tunnel oxide thereby protects the freshly cleaned cell surface from unwanted impurities.

Preferred embodiments of the present invention are described in more detail below with reference to the figures. The Figures show the following:

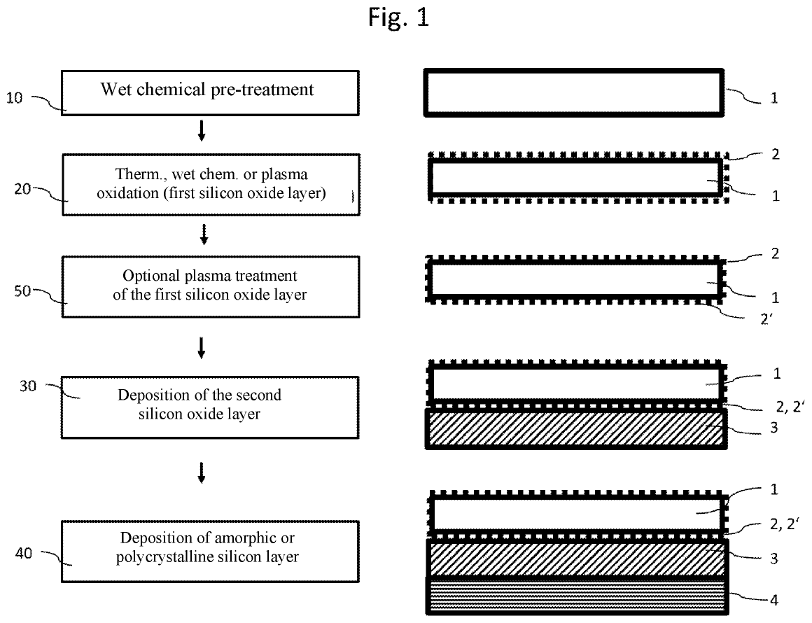

FIG. 1 shows a block diagram for process steps of the process according to the invention and the corresponding intermediate products;

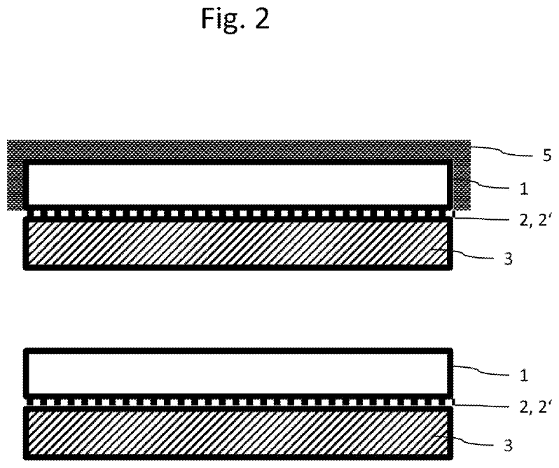

FIG. 2 shows a schematic illustration of an oxidation step using a protective layer; and

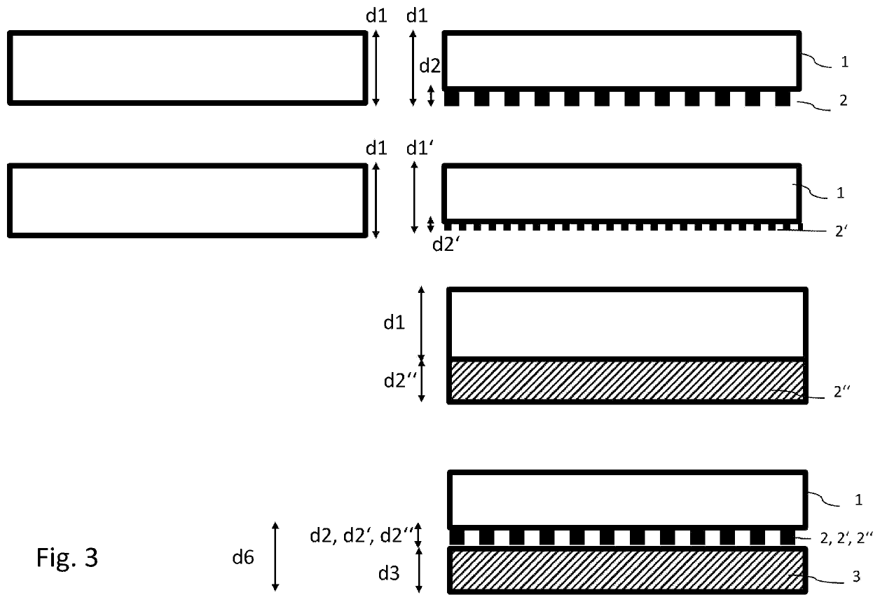

FIG. 3 shows a schematic illustration of different embodiments for applying the silicon oxide layers.

The left side of FIG. 1 shows process steps of the process according to the invention in a schematic block diagram. The right side of FIG. 1 shows the intermediate product obtained after the respective process step.

Accordingly, an optional wet chemical pretreatment 10 of a silicon wafer is carried out first, which comprises, for example, wet chemical cleaning and/or wet chemical texturing, for example on the basis of an alkaline or acid etching process. During this pretreatment, material is removed from the substrate. The result of such a wet chemical cleaning is a silicon wafer 1 with a freshly cleaned and possibly textured cell surface.

Subsequently, if possible immediately after the pretreatment, a thermal and/or wet chemical oxidation 20 of the silicon wafer 1 is carried out, whereby on one or both sides of the wafer the first silicon oxide layer 2 is applied, which protects the cleaned surface and, at least on the first wafer surface, forms the basis of the subsequent tunnel oxide. For this purpose, the silicon wafer 1 is immersed for a few minutes for example in an acidic or alkaline bath containing an oxidizing agent such as ozone, hydrogen peroxide or nitric acid. Subsequently, as indicated in FIG. 1 (right side), the entire surface of the silicon wafer 1 is covered with the first silicon oxide layer 2. Alternatively, the silicon wafers are thermally oxidized at a temperature of about 600° C. in an oxygen-containing atmosphere for about 10 minutes. The wet chemical oxidation or thermal oxidation causes oxygen to diffuse into the substrate surface and oxidize the top layer of the silicon wafer. The thickness of the pretreated silicon wafer d1 (see FIG. 3) does not change as a result of this oxidation. Pretreated solar wafers have a thickness of approximately 120 to 170 μm; thinner wafers will also be used in the future. The thickness of the tunnel oxide is only approximately 1 to 2 nm, so that the wafer thickness is irrelevant for the deposition of the tunnel oxide.

As an alternative to thermal or wet chemical oxidation, the first silicon oxide layer 2 can also be generated on the pretreated silicon substrate 1 directly by a purely oxidative, non-deposition plasma treatment process, in which the uppermost part of the silicon substrate is also oxidized in the presence of oxygen radicals or ions.

In an optional further step 50, the first silicon layer 2 is converted by means of a plasma treatment, at least on one side, into a modified first silicon layer 2′ which differs from the original first silicon layer 2 in thickness, surface texture and/or degree of purity. This step allows the first silicon layer 2, 2′ to be adapted, while retaining its protective effect on the previously cleaned surface of the substrate 1, in terms of purity, absence of defects and overall layer thickness for use as a sublayer of the subsequent overall tunnel oxide.

In a further step 30, the first silicon oxide layer 2, 2′ is coated on the first side (here: the bottom side) of the silicon wafer 1 with a second silicon oxide layer 3 by means of physical or chemical vapor deposition, preferably by means of cathode sputtering or PE-CVD. The resulting tunnel oxide layer is composed of the sum of layers 2 or 2′ and 3.

Subsequently, in a step 40, said second silicon oxide layer 3 is coated with at least a third layer 4 comprising e.g. amorphous silicon. This coating is also carried out by means of physical or chemical vapor deposition and preferably by means of cathode sputtering or PE-CVD.

As a matter of course, steps 50, 30 and 40 can also be performed on the opposite second side (i.e. here: the top side) of silicon wafer 1 or on both wafer sides.

Subsequently, the intermediate product shown in FIG. 1 on the bottom right (if necessary including further layers) can be annealed at a temperature of at least 700° C.

Furthermore, rinsing and drying can take place immediately after step 20 (not shown).

In some cases, it may be desirable to apply a silicon oxide layer to only one side of the silicon wafer. In terms of wet chemical treatment, this is possible with a treatment device in a batch process and in an inline process. Advantageously, cleaning can also be carried out in the same treatment devices.

One-sided wet chemical oxidation or thermal oxidation can be achieved particularly easily using a protective layer 5 (see FIG. 2), which prevents oxidation wherever the silicon wafer is covered with the protective layer 5. Between steps 10 and 20 shown in FIG. 1, the wet-chemically pretreated silicon wafer 1 is provided with a protective layer 5 for this purpose. This layer can cover, for example, one side (here: the top side) of the silicon wafer 1 and optionally the side edges, as shown in FIG. 2, and can consist e.g. of silicon nitride, silicon oxide or a polymer. In step 20, only the free surface (here: the bottom side) of the silicon wafer 1 can thus be oxidized. Subsequently (e.g. after coating with a second silicon oxide layer 3 by means of physical or chemical vapor deposition in step 30), the protective layer 5 can be removed again, for example by an additional wet chemical step (see FIG. 2 below). Such a protective layer 5 may, for example, comprise borosilicate glass which was generated e.g. in a boron diffusion process and can be removed by a hydrofluoric acid-based etching process.

When using a purely oxidative, non-coating plasma treatment process to form the first silicon oxide layer 2 in step 20, single-sided oxidation can be achieved using an in-line continuous system with suitable arrangement of the plasma source and substrate intake, thereby eliminating the need for a protective layer.

Instead of the purely oxidative, non-coating plasma, a coating PVD or PE-CVD process can also be used to form the first silicon oxide layer 2 on the pretreated wafer 1, which can also be applied on one side in a suitable continuous system (see FIG. 3, third illustration from top: 2″). Within the meaning of the invention, firstly either the second oxide layer and then the third, silicon-containing layer or directly the third layer can be deposited on a first oxide layer applied to the wafer in this way, preferably in the same system.

FIG. 3 shows the different embodiments for forming the tunnel oxide and the thicknesses of the substrate and the different layers.

The top illustration shows the first silicon oxide layer 2 of thickness d2 generated in step 20, herein for example only on one side of the pretreated silicon wafer 1 of thickness d1, e.g. by a thermal, chemical or non-coating oxygen-containing plasma. The substrate retains its thickness d1 due to the process.

The second illustration from the top shows the first silicon layer 2′ of thickness d2′, modified in step 50 by plasma treatment, and thus the modified thickness d1′ of the substrate, which is, however, irrelevant due to the above-mentioned size ratios and is only schematically shown.

The third illustration from the top schematically shows the first oxide layer 3 of thickness d2″ applied additively by a plasma treatment process, which is either reinforced by a second oxide layer or used directly as an overall tunnel oxide and can be used with the silicon layer 3.

The bottommost figure in FIG. 3 shows that the total tunnel oxide of thickness d6 optimized for passivated contact is composed of a first silicon oxide layer 2, 2′ or 2″ of thickness d2, d2′ or d2″, which is produced either non-coating (2), optionally modified (2′) or coating (2″), and a second silicon oxide layer 3 of thickness d3 applied by PVD or PECVD.

For the deposition of the first silicon layer (in case 2″) and the second silicon oxide layer 3 in step 30, physical and chemical vapor deposition as well as atomic layer deposition are basically possible, the latter being much more costly due to the low deposition rate. Plasma-enhanced chemical vapor deposition (PE-CVD) in particular allows dense layers to be produced even at higher temperatures. However, the film thickness is more difficult to control at thin film thicknesses than with physical vapor deposition. Both methods, but preferably the latter, would also allow combining the device with the corresponding device for coating the second silicon oxide layer with at least a third layer.

The advantage of cathode sputtering is that no toxic or flammable gases need to be used. Furthermore, the process is very easy to control, also with regard to the thickness and homogeneity of the coatings achieved. Sputtering is a directed process that allows a single-sided dense coating to be deposited without the need for a wrap-around. The density of the deposited layer can be varied in sputtering at moderate substrate temperatures, for example, by changing the process pressure, plasma power and voltage, or in continuous process also by the substrate transport speed.

Different variants are possible for sputtering a silicon oxide layer:
reactive from the metallic or sub-oxide target using DC, pulsed DC or RF excitation;
from oxide target (quartz) with RF excitation.

In terms of cost and material utilization, pulsed DC excitation from the cylindrical magnetron is particularly preferred.

For the design of the overall system, a continuous system with linear coating sources and dynamic coating is particularly preferred. Linear plasma sources with a homogeneous linear coating rate, such as cylindrical or planar magnetrons, are used, in front of which a continuous line of substrates is passed at a constant transport speed and is dynamically coated. Preferably, the substrates are moved horizontally and the coating sources are arranged above the substrates. The silicon substrates are preferably placed on substrate carriers for this purpose, although other orientations are possible, such as vertical transport or coating from bottom to top in the case of horizontal transport.

The substrate carriers loaded with wafers are introduced into the system by means of a vacuum lock and, after passing through the process area equipped with treatment and coating stations, are removed from the system again through the same or a second vacuum lock.

In such a linear continuous system, individual processes can be applied in a vacuum, such as plasma pre-treatment or the application of the first or second oxide layer or the amorphous or polycrystalline silicon layer. Preferably, however, several or all process steps are combined in such a continuous system, whereby, due to the exclusion of the surrounding atmosphere, a higher absence from defects can be achieved and costs can be saved. Optionally, substrate heaters can be integrated into such a system to control the layer properties and deposition rates. Moreover, a further thermal process for annealing the passivated contact layers can be integrated into such a system.

Using linear plasma sources, plasma treatment steps such as the step 50 described, as well as the process variant PE-CVD for the deposition of the oxide and the silicon layers for the formation of the tunnel oxide and the entire passivated contact can also be integrated into a linear continuous system. With suitable design and arrangement of the linear plasma sources, gas supply and removal components and substrate carriers, plasma treatment and layer deposition by PE-CVD can also be carried out on one side in the continuous process. This is a significant advantage of inline PE-CVD compared to static PE-CVD in batch systems with boats as substrate carriers (tube PECVD) and compared to low-pressure CVD (LP-CVD), in which the wafers are also coated in a reactor tube stacked in boats and, compared to continuous systems, no one-sided orientation of the coating source to the substrates prevails.

The wrap-around of a layer deposited by LP-CVD is several mm to cm from the outer edge of the wafer, and several mm of layer wrap on the backside of the substrate is also observed in tubular PE-CVD. In PE-CVD of poly-silicon films in continuous process with linear plasma sources and suitable equipment geometry, no undesired backside coating can be detected in the optical microscope.

1. A process for manufacturing a starting material for a silicon solar cell having passivated contacts, comprising:
providing a silicon wafer having a first side and a second side, the silicon wafer having a first silicon oxide layer on at least the first side;
coating the first silicon oxide layer on the first side with a second silicon oxide layer by physical vapor deposition, chemical vapor deposition, cathode sputtering, or PE-CVD; and
coating the second silicon oxide layer with at least a third layer comprising amorphous silicon and/or polycrystalline silicon and/or nanocrystalline silicon.

2. The process according to claim 1, wherein the first silicon oxide layer has a thickness of 0.5 nm to 3 nm.

3. The process according to claim 1, wherein the first silicon oxide layer is treated using a plasma treatment process before applying the second silicon oxide layer, wherein the treatment with plasma takes place within 48 hours after completion of the coating of the first silicon oxide layer with the second silicon oxide layer.

4. The process according to claim 1, wherein the second silicon oxide layer has a thickness of 0.1 nm to 5 nm.

5. The process according to claim 1, wherein the coating of the second silicon oxide layer with at least the third layer takes place by one or a combination of: physical vapor deposition, chemical vapor deposition, cathode sputtering, or PE-CVD.

6. The process according to claim 1, wherein the third layer comprises a dopant.

7. The process according to claim 1 any one of the preceding claims, wherein providing the silicon wafer with the first silicon oxide layer comprises: i) oxidizing at least the first side of a silicon wafer by one or a combination of: thermal oxidation, wet chemical oxidation, a plasma process and/or ii) heating the silicon wafer having the first silicon oxide layer to at least 100° C. before and/or while the first silicon oxide layer is coated with the second silicon oxide layer.

8. The process according to claim 1, wherein the silicon wafer provided comprises a first silicon oxide layer on the first side and the second side, respectively.

9. The process according to claim 8, wherein simultaneously with the oxidation of at least the first side, also the second side of the silicon wafer is oxidized by one or a combination of: thermal oxidation, wet chemical oxidation, and/or a plasma treatment process to achieve a first silicon oxide layer on the second side.

10. The process of claim 8, further comprising:
coating the first silicon oxide layer on the second side with a second silicon oxide layer using one or a combination of: physical vapor deposition, chemical vapor deposition, cathode sputtering, or PE-CVD.

11. The process of claim 8, further comprising:
coating the first silicon oxide layer on the second side or the second silicon oxide layer on the second side with at least one doped silicon layer.

12. The process according to claim 11, wherein the doped silicon layer is applied by one or a combination of: physical vapor deposition, chemical vapor deposition, cathode sputtering, or PE-CVD.

13. The process according to claim 1, further comprising: annealing the coated silicon wafer at a temperature of at least 700° C.

14. The process according to claim 13, wherein the annealing causes a doped silicon layer to be formed in the silicon wafer on the first side below the first silicon oxide layer and/or a doped silicon layer to be formed in the silicon wafer on the second side below the first silicon oxide layer.

15. The process according to claim 14, wherein the doping level of the formed doped silicon layer depends on the thickness and/or the density of the second silicon oxide layer on the first and second sides, respectively.

16. The process according to claim 1, wherein at least some steps of the process are carried out as part of a continuous process.

17. The process according to claim 1, wherein the coating of the second silicon oxide layer with the third layer takes place within 48 hours after completion of the coating of the first silicon oxide layer with the second silicon oxide layer.

18. The process according to claim 1, wherein the coating of the first silicon oxide layer with the second silicon oxide layer and the coating of the second silicon oxide layer with the third layer takes place in a single continuous system, wherein the wafers are introduced into the continuous system using a vacuum lock before coating and are removed from the continuous system by a vacuum lock after coating.

19. The process according to claim 18, wherein the oxidation of at least the first side of the silicon wafer takes place in the same continuous system.

20. The process of claim 18, wherein the coating of the first silicon oxide layer with the second silicon oxide layer and the coating of the second silicon oxide layer with the third layer take place without vacuum breakage.

21. The process according to claim 1, wherein the first silicon oxide layer and the second silicon oxide layer are identical in terms of their elemental composition.

22.-32. (canceled)
